(19) United States
(12) Patent Application Publication
(10) Pub. No.: US 2025/0344516 A1
(43) Pub. Date: Nov. 6, 2025

(54) ELECTROSTATIC DISCHARGE PROTECTION DEVICE

(71) Applicant: Renesas Design (UK) Limited, Bourne End (GB)

(72) Inventor: Prantik MAHAJAN, Dresden (DE)

(73) Assignee: Renesas Design (UK) Limited, Bourne End (GB)

(21) Appl. No.: 18/655,880

(22) Filed: May 6, 2024

(51) Int. Cl. H01L 27/02

(52) U.S. Cl. CPC H10D 89/814; H10D 89/911

(57) ABSTRACT

An electrostatic discharge (ESD) protection device is provided. The ESD protection device includes an N-type well layer having a first positive N-type diffusion region coupled to an anode terminal; a P-type well layer having a second positive N-type diffusion region coupled to a cathode terminal; a substrate layer; a N-type buried layer provided between the P-type well layer and the substrate layer; and a dielectric layer coupled to a gate terminal. The N-type buried layer has a third N+ diffusion region coupled to a buried layer terminal. The N-type well layer is provided above the P-type well layer. A parasitic circuit is activated within the N-type well layer and the P-type well layer when the anode terminal receives a voltage equal or greater than a first threshold value.

### TECHNICAL FIELD

The present disclosure relates to an electrostatic discharge (ESD) protection device and in particular to a low leakage controlled rectifier, such as a semiconductor controlled rectifier or silicon controlled rectifier (SCR).

### BACKGROUND

Solid-state current controlling devices can be used to manage electrostatic discharge (ESD) issues.

Various ESD protection devices have been reported. US2016099241 describes an n-type metal oxide semiconductor (NMOS) transistor for electrostatic discharge. Another structure is presented in P. Mahajan, S. Suresh, X. M. E. Low, K. J. Hwang and R. Gauthier, “A Robust Scalable ESD Protection Device integrating Drain side Floating P+ Diffusion with tunable ESD Design Window and effective Latch-up immunity for High-Voltage Power Clamp applications,” 2022 44th Annual EOS/ESD Symposium (EOS/ESD), Reno, NV, USA, 2022, pp. 1-8, doi: 10.23919/EOS/ESD54763.2022.9928482.

These devices are limited by significant current leakage, especially as the temperature increases beyond a certain level.

It is an object of the disclosure to address one or more of the above mentioned limitations.

### SUMMARY

According to an aspect of the disclosure there is provided an electrostatic discharge protection device comprising an N-type well layer (110) having a first positive N-type diffusion region (115) coupled to an anode terminal, a P-type well layer (120) having a second positive N-type diffusion region (125) coupled to a cathode terminal, a substrate layer (140); a N-type buried layer (130) provided between the P-type well layer (120) and the substrate layer (140), wherein the N-type buried layer (130) has a third N+ diffusion region (135) coupled to a buried layer terminal; and a dielectric layer (150) coupled to a gate terminal; wherein the N-type well layer (110) is provided above the P type well layer (120); and wherein a parasitic circuit is activated within the N-type well layer (110) and the P-type well layer (120) when the anode terminal receives a voltage equal or greater than a first threshold value (Vt1).

For instance, the substrate layer may be a P-type substrate layer or an insulator layer.

For instance, the first threshold value may be referred to as trigger voltage.

Optionally, the first threshold value is adjustable by applying a biasing voltage at the buried layer terminal. For instance, the first threshold value increases as the biasing voltage increases.

Optionally, the N-type well layer (110) has a first positive P-type diffusion region (116) coupled to a floating terminal; and the P-type well layer (120) has a second positive P-type diffusion region (126) coupled to a bulk terminal.

Optionally, the device further comprises a biasing resistor (Rnb1) coupling the buried layer terminal to the bulk terminal.

Optionally, the dielectric layer is a gate oxide layer (GOX) or a High-K Metal Gate (HKMG) layer coupled to the gate terminal.

Optionally, when a positive voltage is applied to the anode terminal above the first threshold value, a current passes from the first positive N-type diffusion region (115) to the second positive N-type diffusion region (125) via the parasitic circuit.

Optionally, the parasitic circuit comprises a first parasitic transistor (111) coupled to a second parasitic transistor (112).

Optionally, the first parasitic transistor (111) is coupled to the bulk terminal via a first parasitic resistor (Rp) and wherein the second parasitic transistor (112) is coupled to the anode terminal via a second parasitic resistor (Rn).

Optionally, the first parasitic transistor (111) has an emitter coupled to the second positive N-type diffusion region (125), and a base coupled to the second positive P-type diffusion region (126) via the first parasitic resistor (Rp).

Optionally, wherein the second parasitic transistor (112) has an emitter coupled to the first positive P-type diffusion region (116), and a base coupled the first positive N-type diffusion region (115) via the second parasitic resistor (Rn).

Optionally, wherein the N-type well layer (110) extends between a first end provided at an edge of the device, and a second end located below the first positive P-type diffusion region (116).

Optionally, the first positive P-type diffusion region (116) extends along a depth axis (z), and wherein the first positive P-type diffusion region (116) is segmented along the depth axis to form a segmented region having a plurality of diffusions regions alternating between positive P-type and positive N-type.

Optionally, the N-type well layer (110) extends between a first end provided at an edge of the device and a second end located below the gate layer (150).

Optionally, the first positive P-type diffusion region (116) extends along a depth axis (z), and wherein the first positive P-type diffusion region (116) is segmented along the depth axis to form a segmented region having a plurality of diffusions regions alternating between positive P-type and positive N-type, and wherein the segmented region is juxtaposed to a non-segmented positive P-type region.

Optionally, the device further comprises at least one of a gate resistor (Rg) coupling the gate terminal to the cathode terminal, and a gate capacitor (Cg) coupling the gate terminal to the anode terminal.

For instance, the gate resistor Rg and the gate capacitor may form a RC trigger circuit.

Optionally, the device further comprises a blocking layer (160) covering at least partially a top surface of the N-type well layer (110).

Optionally, the blocking layer (160) is a silicide block layer (SBLK) or a resist protective oxide (RPO).

Optionally, the first threshold value is a function of an overlap (Lov) between the NW layer (110) and the gate layer (150). For instance, as the overlap increases the first voltage decreases.

Optionally, the device has a holding voltage (Vh), and the holding voltage is a function of a diffusion length (Lfp) of the first positive P-type diffusion region (116). For instance, as the diffusion length (Lfp) increases the holding voltage increases.

### DESCRIPTION OF THE DRAWINGS

The disclosure is described in further detail below by way of example and with reference to the accompanying drawings, in which:

FIG. 1A is a cross-sectional view of a solid-state electrostatic discharge (ESD) protection device according to the disclosure;

FIG. 1B is a close-up view of the device of FIG. 1, showing the parasitic circuit;

FIG. 2A is a perspective three-dimensional view of the P+ diffusion region in the NW layer when the NW layer extends up to a region below the GOX layer; and

FIG. 2B is perspective three-dimensional view of the P+ diffusion region in the NW layer when the NW layer extends up to a region below the P+ diffusion region.

### DESCRIPTION

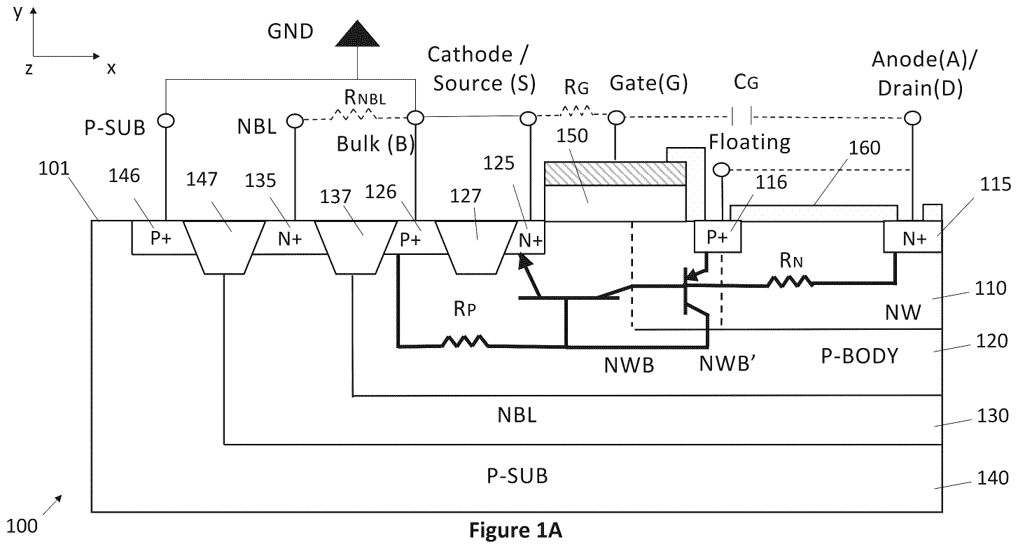

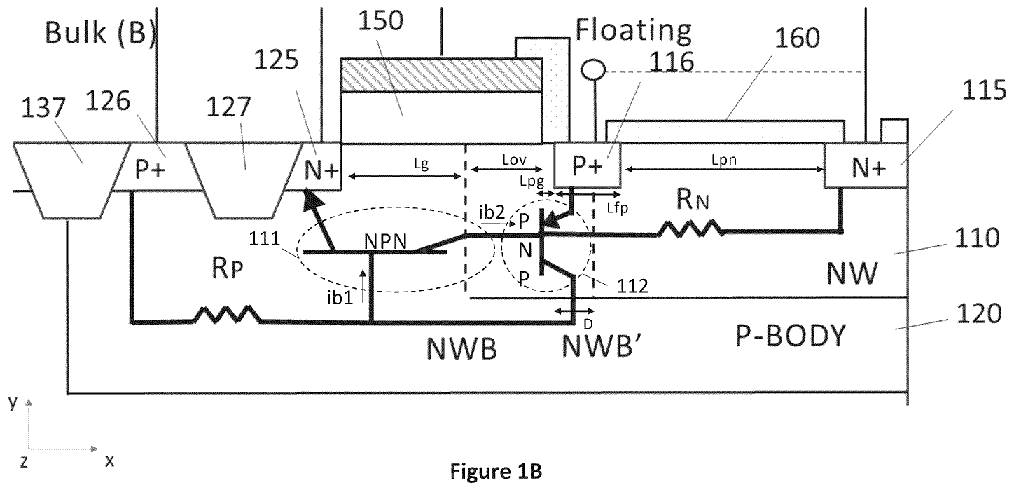

FIG. 1A is a cross-sectional view of a solid-state electrostatic discharge (ESD) protection device according to the disclosure. The circuit 100 includes an embedded parasitic circuit shown in bold lines. FIG. 1B is a close-up view of the device of FIG. 1, showing the parasitic circuit in more detail.

The circuit 100 can be used as an electrostatic discharge (ESD) protection device and may also be referred to as a semiconductor controlled rectifier (SCR) or more specifically as a Low Trigger Voltage/High Holding Voltage Silicon Controlled Rectifier (LVT/HHVSCR).

The device 100 includes a N-Well layer (NW) 110, a P-Well layer (P-BODY) 120, a N-buried layer (NBL) 130, and a P substrate layer (P-SUB) 140. The layers 120, 130 and 140 have a horizontal region and a vertical region forming an L shape cross section. The NBL layer 130 is provided between the P-SUB layer 140 and the P-BODY layer 120 to provide vertical isolation between these layers. In particular, it isolates the SCR circuit from the substrate (P-SUB), thus reducing possibility of substrate noise coupling and leakage. The NBL layer may be implemented as a deep N-type well implant. The N-Well layer 110 has a rectangular cross section located on top of the P-BODY layer 120. The layers 110 to 140 are nested to form a top surface 101.

The top section of the vertical region of the layer 140 has a P+ diffusion region 146 connected to a substrate terminal. The top section of the vertical region of the layer 130 has an N+ diffusion region 135 connected to a NBL terminal. The top section of the vertical region of the layer 120 has an N+ diffusion region 125 connected to a cathode or source terminal, and a P+ diffusion region 126 connected to a bulk terminal. The cathode is coupled to ground.

The top section of the layer 110 has an N+ diffusion region 115 connected to a drain or anode terminal, and a P+ diffusion region 116 connected to a floating terminal. For ESD SCR operation, the floating terminal should be connected to the drain terminal. For instance, the floating terminal and the drain terminal may be shortened through backend-of-the-line BEOL wiring.

The N+ and P+ diffusions regions 125 and 126 are separated by a lateral isolation region 127 also referred to as (STI-Shallow Trench Isolation). The N+ and P+ diffusions regions 135 and 126 are separated by a lateral isolation region 137. The N+ and P+ diffusions regions 135 and 146 are separated by a lateral isolation region 147.

A dielectric layer 150 such as a Gate Oxide layer GOX or a High-K Metal Gate layer HKMG, is provided on a region of the top surface 101 between the N+ region 125 and the P+ region 116. The dielectric layer 150 may be coated with a polysilicon layer or with a metal layer.

The dielectric layer 150 is connected to a gate terminal.

A blocking layer (160) also referred to as dummy gate, may be provided on top of the NW layer 110 to reduce current leakage due to surface states/traps. The layer 160 covers at least partially a top surface of the N-type well layer (110). In this example the blocking layer 160 also covers part of the gate layer 150. The blocking layer may be a Silicide Block layer (SBLK) or a resist protective oxide (RPO).

The length of the NW layer 110 may vary. In a first example the NW layer 110 extends between a first end at an edge of the device and a second end labelled (NWB′) located below the positive P-type diffusion region 116.

In a second example the NW layer 110 extends between a first end at an edge of the device and a second end labelled (NWB) located below the GOX layer 150.

The overlap between the NW layer 110 and the GOX layer 150 is shown by the NW-GOX length overlap (Lov). When the NW layer 110 extends up to the boundary NWB, the Gate length (Lg) extends between the N+ diffusion region 125 and the boundary NWB. When the NW layer extends up to the boundary NWB′, the Gate length Lg is the length of the dielectric layer 150.

The P+ region 116 has a Pseudo-Floating P+ diffusion length (Lfp). The distance between the N+ region 115 and the P+ region 116 defines the Pseudo-Floating P+ diffusion to Drain-side N+ diffusion spacing (Lpn). The distance between the P+ region 116 and the GOX layer 150 defines the Gate to Pseudo-Floating P+ diffusion spacing (Lpg).

The bulk terminal and the source terminal may be connected to form a bulk/source terminal. The bulk/source terminal and the P-SUB terminal may be connected to ground.

Optionally, a resistor Rnb1 may be provided between the NBL terminal and the Bulk/Source terminal. The resistor Rnb1 can be tuned to bias the NBL layer 130 at a positive potential (above GND). The NBL bias can be used to regulate the potential of the P-BODY layer 120, thus modulating the NPN base current ib1 and thus, the parasitic NPN (& SCR) turn-on.

A Gate-to-Source Resistor Rg may also be provided between the source terminal and the gate terminal. A Gate-to-Drain Capacitor (Cg) may be provided between the gate terminal and the drain terminal. When both Rg and Cg are provided they form an RC trigger circuit delivering a gate voltage Vg at the gate terminal. Alternatively, the gate voltage Vg may be provided using Rg alone or Cg alone. When only Rg is provided there is no connection (short wiring) between the gate terminal and the drain terminal. When only Cg is provided the gate terminal is connected to the cathode terminal, for instance through backend-of-the-line BEOL wiring.

The parasitic circuit, also referred to as SCR parasitic circuit is shown in bold lines in FIGS. 1A and 1B. It includes a horizontal NPN parasitic structure (parasitic transistor 111) coupled to a vertical PNP parasitic structure (parasitic transistor 112) and two parasitic resistors R_{P} and R_{N}.

The emitter of transistor 111 is connected to the N+ region 125, while the emitter of the transistor 112 is connected to P+ region 116. The collector of transistor 111 is connected to the base of transistor 112, and the collector of transistor 112 is connected to the base of transistor 111. The first parasitic resistor R_{P} connects the base of 111 to the P+ region 126. The second parasitic resistor R_{N} connects the base of 112 to the N+ region 115.

The parasitic circuit becomes activated when an ESD pulse voltage applied at the Anode/drain terminal reaches a threshold value referred to as the Trigger Voltage (Vt1). This may happen during an ESD event that applies a voltage stress pulse at the Anode/Drain terminal.

The device 100 can be tested using a transmission line pulse (TLP), having voltage pulses of increasing amplitudes.

When a positive voltage pulse is applied to the anode terminal connected to the N+ diffusion region 115, the junction at the NW boundary NWB breaks down. If the voltage pulse is relatively low (low stress pulse voltage), the ESD device does not turn on and a leakage current may pass directly between the N+ region 115 at the anode to the N+ region 125 at the cathode at a shallow depth within the layers 110 and 120. When the voltage pulse increases in amplitude the ESD device turns on and an ESD current passes from the anode to the cathode via the SCR parasitic circuit. The amplitude of the voltage pulse may be increased gradually until the SCR circuits turns on.

As the junction at the NWB breaks down a collector current is provided to the collector of the NPN transistor 111, which turns on. A base current ib2 passes to the second transistor 112, which also turns on. When both parasitic transistors are on, a current path is created between the anode and the cathode terminal via a deeper trajectory within the P-Body layer 120. This permits more ESD current to go through the device 100 without significant current leakage. The preferred ESD current conduction path is through the parasitic horizontal NPN and vertical PNP transistors 111 and 112. So, the device 100 may be referred to as a self-started device or self-started SCR device.

The current vs voltage characteristics of ESD devices can be described using various key parameters which include the clamping voltage Vc1, the holding voltage Vh, and the trigger voltage Vt1. These parameters have been described in various publications, see for instance FIG. 1 (showing the Transmission-Line Pulse (TLP) current versus TLP voltage) of publication by P. Mahajan, R. Kumar, R. Gauthier and K. J. Hwang, “Optimization of GGNMOS Devices for High-Voltage ESD Protection in BCDLite Technology,” 2020 International EOS/ESD Symposium on Design and System (IEDS), CHENGDU, China, 2021, pp. 1-6, doi: 10.23919/IEDS48938.2021.9468827.

The circuit 100 may operate to provide a so called snap-back protection. The snap-back effect lowers the clamping voltage Vc1 after the protection is triggered. The trigger voltage Vt1 is the maximum voltage before the device turns on and snap back to the holding voltage Vh. The holding voltage is the lowest voltage when the snap-back protection has turned on. The lower is the holding voltage, the better is the clamping voltage Vc1. However, if the holding voltage is too low this can lead to potential Latch-up issue. For this reason, the holding voltage Vh always need to have some margin (e.g. 10%) above the supply voltage (Vdd).

The N-buried layer (NBL) 130 may be biased by applying a bias voltage Vbias to the NBL terminal. Alternatively, no bias voltage may be applied.

When applying a bias voltage Vbias, the NBL terminal and the bulk terminal should be connected to each other. For instance, the NBL terminal and the bulk terminal may be shortened through backend-of-the-line BEOL wiring. This can be used to tune the trigger voltage Vt1. By applying a positive bias voltage to the NBL terminal, the trigger voltage Vt1 is increased. More generally the trigger voltage Vt1 increases as the bias voltage increases. The resistor R_{NBL} can also be used to regulate the bias voltage applied at the NBL terminal. Alternatively, the resistor R_{NBL} can be used without applying an additional bias voltage Vbias at the NBL terminal.

The trigger voltage Vt1 can also be changed via the Rg and/or Cg. As Rg increases the base current ib1 of the NPN transistor 111 increases and Vt1 decreases. Increasing the base current ib1 also facilitate turn on of the transistor 111. Similarly, as Cg increases, Vt1 also decreases.

In addition, the trigger voltage Vt1 could be modulated by varying the Lov parameter (overlap of the NW layer 110 with the Gate layer 150). The Lov parameter may also be tuned to regulate the parasitic transistor (NPN) 111 turn-on. As the Lov parameter increases, the effective base width of the parasitic transistor (NPN) 111 decreases. So, Vt1 & Vh are expected to decrease since the parasitic Bipolar Current Gain (β) is high. Also, effective Lg would be lowered, as Lov increases. This might lead to channel leakage. Therefore, a balance should be struck. For instance, Lov can be designed to vary between 0.33× to 0.5× of Lg.

As mentioned above, the length of the NW layer 110 may vary along the x axis. In a first example the NW layer extends up to a region below the P+ diffusion region 116 (NW boundary NWB′). In a second example the NW layer extends up to a region below the GOX layer 150 (NW boundary NWB).

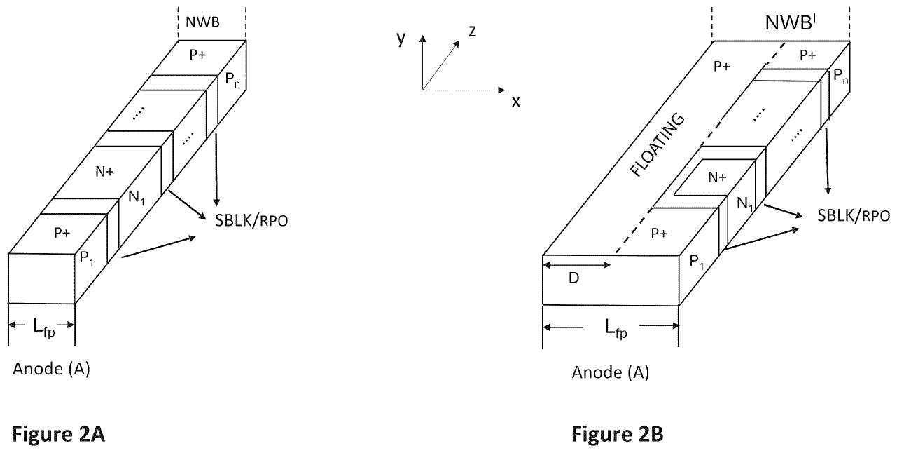

FIG. 2A is a perspective three-dimensional view of the P+ diffusion region 116 of the NW layer 110 when the NW layer extends up to a region below the GOX layer 150. So, in this example the N-Well boundary NWB is underneath the Gate. This implementation permits a better SCR parasitic circuit formation.

The P+ diffusion region 116 extends along a depth axis (z). The region 116 is segmented along the depth axis (z) to form a segmented region having a plurality of diffusions regions alternating between positive P-type and positive N-type: P+/N+/P+/N+ etc. . . . In this example the region 116 is described as fully segmented and has a number N of segments. The segments are separated by a blocking layer such as SBLK or RPO. Such a segmentation permits to tune by design the holding voltage Vh to a desired value. Alternatively, the diffusion region 116 of FIG. 2A could be continuous and made of a single P+ region.

FIG. 2B is a perspective three-dimensional view of the P+ diffusion region 116 of the NW layer 110 when the NW layer extends up to a region below the P+ diffusion region (NWB′). So, in this example the N-Well boundary NWB′ is underneath the Pseudo-Floating P+ diffusion. The region 116 is only partially segmented due to the presence of the floating P+ region besides the segmented region of N segments alternating P+/N+/P+/N+ etc . . . Alternatively the bar of FIG. 2B could be made of a single P+ region.

The P+ diffusion region (116) extends along the length axis (x) and has a length Lfp. Compared with FIG. 2A, the length Lfp has now increased by the length D. As Lfp increases, the holding voltage Vh also increases, hence providing a better latch-up immunity. However, this also increases the footprint of the device.

The holding voltage Vh can be tuned by varying the Lfp parameter (Anode/Drain-side Pseudo-Floating P+ diffusion length) or by varying the ratio of P+ diffusion contacts to neighboring N+ diffusion contacts (along the z direction) or by varying Lpg parameter (Gate edge to Anode/Drain-side Pseudo-Floating P+ diffusion spacing), in case of non-self-aligned structure (when Lpg is null, the gate layer 150 and the P+ region 116 are self-aligned).

The trigger Vt1 and the holding voltage Vh can be tuned simultaneously by varying the Lpn parameter (Anode/Drain-side Pseudo-Floating P+ diffusion to Drain-side N+ diffusion spacing).

There is therefore a trade-off between size and holding voltage value. Depending on the application, an implementation according to FIG. 2A or FIG. 3B may be preferred.

The circuit 100 of the disclosure provides an efficient ESD clamp with a reduced footprint and a low standby leakage current. In addition, the trigger voltage Vt1 is relatively low and tunable. The trigger voltage can be tuned by designed as described above or by applying a bias voltage to the NBL terminal.

The holding voltage Vh is high and tunable by design.

For example, the circuit of FIG. 1 can be designed to achieve the following structures:
(i) Low-leakage LVTSCR-based ESD structures for 1.1V IO and Supply pins
(ii) Low-leakage LVTSCR-based ESD structures for 1.8V to 3.3V IO pins
(iii) Low-leakage HHVSCR-based ESD structures for 5V+IO and Supply pins

The ESD protection device of the disclosure may be implemented using Bulk technology or SOI technology. For SOI technology the substrate can change from Bulk (P-SUB) to SOI (Insulator).

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. An electrostatic discharge protection device comprising
an N-type well layer having a first positive N-type diffusion region coupled to an anode terminal,
a P-type well layer having a second positive N-type diffusion region coupled to a cathode terminal,
a substrate layer;
a N-type buried layer provided between the P-type well layer and the substrate layer, wherein the N-type buried layer has a third N+ diffusion region coupled to a buried layer terminal; and
a dielectric layer coupled to a gate terminal;
wherein the N-type well layer is provided above the P-type well layer; and
wherein a parasitic circuit is activated within the N-type well layer and the P-type well layer when the anode terminal receives a voltage equal or greater than a first threshold value.

2. The device as claimed in claim 1, wherein the first threshold value is adjustable by applying a biasing voltage at the buried layer terminal.

3. The device as claimed in claim 1, wherein the N-type well layer has a first positive P-type diffusion region coupled to a floating terminal; and wherein the P-type well layer has a second positive P-type diffusion region coupled to a bulk terminal.

4. The device as claimed in claim 3, further comprising a biasing resistor coupling the buried layer terminal to the bulk terminal.

5. The device as claimed in claim 1, wherein the dielectric layer is a gate oxide layer or a High-K Metal Gate layer coupled to the gate terminal.

6. The device as claimed in claim 1, wherein when a positive voltage is applied to the anode terminal above the first threshold value, a current passes from the first positive N-type diffusion region to the second positive N-type diffusion region via the parasitic circuit.

7. The device as claimed in claim 3, wherein the parasitic circuit comprises a first parasitic transistor coupled to a second parasitic transistor.

8. The device as claimed in claim 7, wherein the first parasitic transistor is coupled to the bulk terminal via a first parasitic resistor and wherein the second parasitic transistor is coupled to the anode terminal via a second parasitic resistor.

9. The device as claimed in claim 8, wherein the first parasitic transistor has an emitter coupled to the second positive N-type diffusion region, and a base coupled to the second positive P-type diffusion region via the first parasitic resistor.

10. The device as claimed in claim 9, wherein the second parasitic transistor has an emitter coupled to the first positive P-type diffusion region, and a base coupled the first positive N-type diffusion region via the second parasitic resistor.

11. The device as claimed in claim 1, wherein the N-type well layer extends between a first end provided at an edge of the device, and a second end located below the first positive P-type diffusion region.

12. The device as claimed in claim 11, wherein the first positive P-type diffusion region extends along a depth axis, and wherein the first positive P-type diffusion region is segmented along the depth axis to form a segmented region having a plurality of diffusions regions alternating between positive P-type and positive N-type.

13. The device as claimed in claim 1, wherein the N-type well layer extends between a first end provided at an edge of the device and a second end located below the gate layer.

14. The device as claimed in claim 13, wherein the first positive P-type diffusion region extends along a depth axis, and wherein the first positive P-type diffusion region is segmented along the depth axis to form a segmented region having a plurality of diffusions regions alternating between positive P-type and positive N-type, and wherein the segmented region is juxtaposed to a non-segmented positive P-type region.

15. The device as claimed in claim 1, further comprising at least one of a gate resistor coupling the gate terminal to the cathode terminal, and a gate capacitor coupling the gate terminal to the anode terminal.

16. The device as claimed in claim 1, further comprising a blocking layer covering at least partially a top surface of the N-type well layer.

17. The device as claimed in claim 16, wherein the blocking layer is a silicide block layer or a resist protective oxide.

18. The device as claimed in claim 1, wherein the first threshold value is a function of an overlap between the NW layer and the gate layer.

19. The device as claimed in claim 1, wherein the device has a holding voltage, and wherein the holding voltage is a function of a diffusion length of the first positive P-type diffusion region.
